(19) United States
(12) Patent Application Publication
(10) Pub. No.: US 2015/0333040 A1
(43) Pub. Date: Nov. 19, 2015

(54) SEMICONDUCTOR DEVICE PACKAGE

(71) Applicant: HANA MICRON INC., Asan-si Chungcheongnam-do (KR)

(72) Inventor: Jin-Wook JEONG, Asan-si (KR)

(73) Assignee: HANA MICRON LNC, Asan-si, Chungcheongnam-do (KR)

(21) Appl. No.: 14/652,571

(22) PCT Filed: Apr. 16, 2013
(86) PCT No.: PCT/KR2013/003182

§ 371 Date: Jun. 16, 2015

(30) Foreign Application Priority Data
Dec. 17, 2012 (KR) 10-2012-147344

(51) Int. Cl. H01L 25/065; H01L 23/48; H01L 23/31

(52) U.S. Cl. CPC H01L 25/0657; H01L 23/3107; H01L 23/481

(57) ABSTRACT

A package for a semiconductor device having a fan-out structure in which input/output terminals are disposed adjacent to at least one first semiconductor chip and electrically connected to the at least one first semiconductor chip may include a second semiconductor chip spaced apart from the input/output terminals and be opposed to the at least one first semiconductor chip. The semiconductor device package may ensure an improved degree of integration and may improve connection stability between the input/output terminals and wirings. Accordingly, a reliability of the semiconductor device package may be enhanced.

### BACKGROUND

1. Field

The invention relates to packages for semiconductor devices, and more particularly, the invention relates to packages for semiconductor devices having fan-out structures in which input/output terminals are disposed at an outside of the semiconductor chips.

2. Related Technology

Recently, as electronic apparatuses are widely used for many applications, packing technologies for a semiconductor chip applied to various electronic apparatuses are required to ensure that a recent semiconductor chip package has a high capacity, a thin thickness, a minute size, etc. A wafer level package (WLP) technology has been developed as an example of the solutions to satisfy these requirements.

In the WLP technology, when a semiconductor device has a fan-in structure in which input/output terminals are disposed at an inside of a semiconductor chip, a distance between the input/output terminals have to be reduced as the semiconductor chip has a decreased size. However, there is a limit to reduce the distance between the input/output terminals in accordance with a miniaturization of the semiconductor chip. Further, when the distance between the input/output terminals is continuously reduced, a layout for standard input/output terminals may not be properly applied.

Considering such problems, it has been developed a new wafer level packaging technology for a semiconductor device having a fan-out structure in which the input/output terminals are disposed at an outside of a semiconductor chip. A package for a semiconductor device obtained by this wafer level packaging technology for the semiconductor device having the fan-out structure may include standard input/output terminals arranged in a standard layout even though a size of a semiconductor chip is decreased continuously. However, since the package for the semiconductor device having the fan-out structure has a relatively large size compared to the package for the semiconductor device having the fan-in structure, a size of the package for a semiconductor device having the fan-out structure may be larger than that of the package for the semiconductor device having the fan-in structure when the semiconductor devices have the same sizes.

### SUMMARY

Example embodiments of the invention provide a package for a semiconductor device having a fan-out structure so as to ensure an improved degree of integration and to enhance a space efficiency of the semiconductor device.

According to one aspect of the invention, there is provided a package for a semiconductor device having a fan-out structure in which input/output terminals are disposed adjacent to at least one first semiconductor chip and electrically connected to the at least one first semiconductor chip. The package for a semiconductor device may include a second semiconductor chip spaced apart from the input/output terminals and be opposed to the at least one first semiconductor chip.

In example embodiments, the package for the semiconductor device may additionally include a first molding member enclosing the first semiconductor chip and a second molding member enclosing the second semiconductor chip.

In example embodiments, the package for the semiconductor device may additionally include a filling member disposed between the first semiconductor chip and the second semiconductor chip.

In example embodiments, the second molding member may include an extended portion surrounding the input/output terminals. The input/output terminals may be partially exposed form the extended portion.

In example embodiments, each of the input/output terminals may include a molding wiring passing through the extended portion of the second molding member and a connection wiring protruding from the extended portion.

In example embodiments, each of the input/output terminals may include a stacked solder ball buried in the extended portion of the second molding member and exposed from the extended portion.

In example embodiments, the package for the semiconductor device may additionally include wirings buried in the first molding member and connected to the input/output terminals.

In example embodiments, the first semiconductor chip may include a first connection pad and the second semiconductor chip may include a second connection pad contacting the first connection pad.

In example embodiments, the package for the semiconductor device may additionally include a plurality of first semiconductor chips stacked on the second semiconductor chip, a first molding member enclosing the plurality of first semiconductor chips and a second molding member enclosing the second semiconductor chip.

In example embodiments, the input/output terminals may pass through the second molding member. Each of the first semiconductor chips may include a connection pad. The package for the semiconductor device may additionally include a connection member electrically connecting the connection pad with the input/output terminals.

In example embodiments, the package for the semiconductor device may additionally include a through-silicon via (TSV) wirings electrically connecting the first semiconductor chips to each other.

### BRIEF DESCRIPTION OF THE DRAWINGS

FIG. 1 is a cross-sectional view illustrating a package for a semiconductor device in accordance with example embodiments of the invention;

FIG. 2 is a cross-sectional view illustrating a package for a semiconductor device in accordance with some example embodiments of the invention;

FIG. 3 is a cross-sectional view illustrating a package for a semiconductor device in accordance with some example embodiments of the invention;

FIG. 4 is a cross-sectional view illustrating a package for a semiconductor device in accordance with some example embodiments of the invention;

FIG. 5 is a cross-sectional view illustrating a package for a semiconductor device in accordance with some example embodiments of the invention;

FIG. 6 is a cross-sectional view illustrating a package for a semiconductor device in accordance with some example embodiments of the invention;

FIG. 7 is a cross-sectional view illustrating a package for a semiconductor device in accordance with some example embodiments of the invention;

FIG. 8 is a cross-sectional view illustrating a package for a semiconductor device in accordance with some example embodiments of the invention; and

FIG. 9 is a cross-sectional view illustrating a package for a semiconductor device in accordance with some example embodiments of the invention.

### DESCRIPTION OF EMBODIMENTS

Various embodiments will be described more fully hereinafter with reference to the accompanying drawings, in which some embodiments are shown. The invention may, however, be embodied in many different forms and should not be construed as limited to the embodiments set forth herein. Rather, these embodiments are provided so that this description will be thorough and complete and will fully convey the scope of the invention to those skilled in the art. In the drawings, the sizes and relative sizes of layers and regions may be exaggerated for clarity.

Like numerals refer to like elements throughout. As used herein, the term “and/or” includes any and all combinations of one or more of the associated listed items. It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the invention. The terminology used herein is for the purpose of describing particular embodiments only and is not intended to be limiting of the invention. As used herein, the singular forms “a,” “an” and “the” are intended to include a plurality of forms as well, unless the context clearly indicates otherwise. It will be further understood that the terms “comprises” and/or “comprising,” when used in this specification, specify the presence of stated features, integers, steps, operations, elements and/or components, but do not preclude the presence or addition of one or more other features, integers, steps, operations, elements, components and/or groups thereof.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

### Embodiments

A package for a semiconductor device having a fan-out structure in accordance with example embodiments of the invention may include a first semiconductor chip, a second semiconductor chip, input/output terminals, etc. The first semiconductor chip may be initially provided in the package for the semiconductor device of the fan-out structure and may be electrically connected to the input/output terminals. In the package for the semiconductor device having the fan-out structure, the input/output terminals adjacent to the first semiconductor chip may be disposed at an inside and an outside of the package for the semiconductor device. That is, the input/output terminals may be disposed at the outside of the first semiconductor chip as well as at the inside of the first semiconductor chip.

The second semiconductor chip may be disposed at the inside of the fan-out structure where the input/output terminals are not located. In this case, the second semiconductor chip may substantially face the first semiconductor chip. The first semiconductor chip may include a first connection pad and the second semiconductor chip may include a second connection pad. As the first and the second connection pads make contact with each other, the first and the second semiconductor chips may be electrically connected to each other.

In the package for the semiconductor device, the second semiconductor chip may be disposed to be corresponded to the first semiconductor chip in an inner space of the fan-out structure where the input/output terminals are not located. Therefore, a space efficiency of the package for the semiconductor device may be enhanced to thereby ensure an increased degree of integration.

Additionally, the package for the semiconductor chip may include a first molding member and a second molding member which may substantially enclose the first and the second semiconductor chips, respectively. Wirings may be generally provided in the first molding member. The input/output terminals may make contact with the wirings so that the first semiconductor chip may be electrically connected to the input/output terminals. For example, the input/output terminals may be spaced apart from the second molding member substantially enclosing the second semiconductor chip, or may be partially buried in the second molding member.

Furthermore, the package for the semiconductor device may include a first semiconductor chip unit in which a plurality of first semiconductor chips are stacked. For example, the first semiconductor chip unit may include at least two or more first semiconductor chips stacked on the second semiconductor chip. In this case, the lowermost first semiconductor chip of the first semiconductor chip unit may substantially correspond to the second semiconductor chip.

FIG. 1 is a cross-sectional view illustrating a package for a semiconductor device package in accordance with example embodiments of the invention.

As illustrated in FIG. 1, a package for a semiconductor device 10 may include a first semiconductor chip 11, a second semiconductor chip 21, input/output terminals 15, a molding member 19, wirings 17, etc. In example embodiments, the package for the semiconductor device 10 may have a fan-out structure in which the input/output terminals 15 are disposed at an outside of the first semiconductor chip 11. Each of the input/output terminals 15 may include, e.g., a solder ball. Thus, the package for the semiconductor device 10 may have a substantially standard layout even though the first semiconductor chip 11 has extremely small size.

According to example embodiments, the molding member 19 may protect the first semiconductor chip 11 from an external environment such as a physical damage, a chemical reaction, an electrical shock or the like. The molding member 19 may be formed using a polymer material. The molding member 19 may have a structure enclosing the first semiconductor chip 11. For example, the first semiconductor chip 11 may be partially or fully buried in the molding member 19. Example of the polymer material for the molding member 19 may include epoxy compound.

As described above, when the package for the semiconductor device 10 has the molding member 19, the input/output terminals 15 may contact a bottom face of the molding member 19. Here, each of the input/output terminals 15 may make contact with the wirings 17, and thus the input/output terminals 15 may be electrically connected to the first semiconductor chip 11. For example, the wirings 17 may be substantially buried in the molding member 19 while exposing top faces thereof.

According to example embodiments, the first semiconductor chip 11 may include at least one first connection pad 13 for an electrical connection with the second semiconductor chip 21. Here, the first connection pad 13 may be exposed from the bottom face of the molding member 19 with which the input/output terminals 15 make contact.

The second semiconductor chip 21 may be disposed at an inside of the fan-out structure. For example, the second semiconductor chip 21 may be disposed at the inside of the fan-out structure where the input/output terminals 15 are not positioned. The second semiconductor chip 21 may be separated from the input/output terminals 15. The second semiconductor chip 21 may substantially face the first semiconductor chip 11. That is, the second semiconductor chip 21 may be disposed adjacent to the bottom face of the molding member 19. Additionally, the second semiconductor chip 21 may include at least one second connection pad 23 for an electrical connection with the first semiconductor chip 11.

In example embodiments, the second connection pad 23 of the second semiconductor chip 21 and the first connection pad 13 of the first semiconductor chip 11 may make contact with each other so that the second semiconductor chip 21 may be electrically connected to the first semiconductor chip 11. When the first semiconductor chip 11 includes a plurality of first connection pads 13 and the second semiconductor chip 21 also includes a plurality of second connection pads 23, each of the first connection pads 23 may make contact with each of the second connection pads 23.

In some example embodiments, some of the second connection pads 23 of the second semiconductor chip 21 may not contact the first connection pads 13 of the first semiconductor chip 11. In this case, some of the second connection pads 23 of the second semiconductor chip 21 may make contact with some of the wirings 17 adjacent to the first semiconductor chip 11. Accordingly, some of the wirings 17 may contact the second connection pads 23 of the second semiconductor chip 21 and others of the wirings 17 may make contact with the input/output terminals 15 as described above. However, electrical connections between the second connection pads 23 of the second semiconductor chip 21 as illustrated in FIG. 1 may be advantageously varied based on a circuit configuration of the package for the semiconductor device 10.

According to example embodiments, when the package for the semiconductor device 10 has the fan-out structure, the second semiconductor chip 21 corresponding to the first semiconductor chip 11 may be disposed at the inside of the fan-out structure where the input/output terminals 15 are not located. Accordingly, without requiring additional components or processes, the space efficiency of the package for the semiconductor device 10 may be greatly improved by changing the positional relationship between the first and the second semiconductor chips 11 and 21. As a result, the package for the semiconductor device 10 according to example embodiments may have an improved degree of integration as compared to a conventional semiconductor device having a fan-out structure.

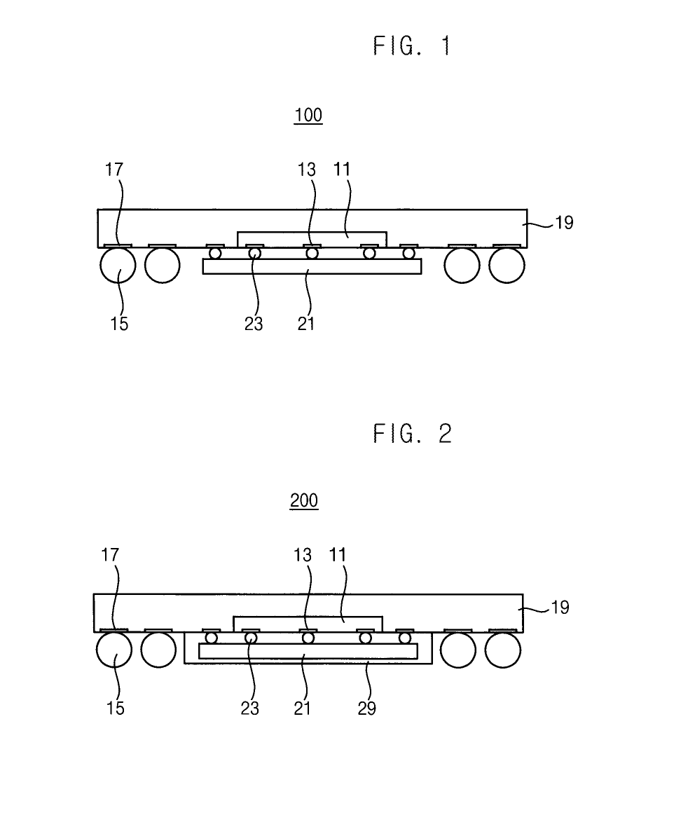

FIG. 2 is a cross-sectional view illustrating a package for a semiconductor device in accordance with some example embodiments of the invention. The package for the semiconductor device 100 in FIG. 2 may have a configuration substantially the same as or similar to that of the package for the semiconductor device 10 described with reference to FIG. 1 except a second molding member 129 substantially enclosing a second semiconductor chip 121. The package for the semiconductor device 100 illustrated in FIG. 2 may include a first molding member 119 substantially enclosing a first semiconductor chip 111 and the second molding member 129 substantially enclosing the second semiconductor chip 121.

Referring to FIG. 2, the package for the semiconductor device 100 may include the second molding member 129 to substantially bury the second semiconductor chip 121. In this case, the package for the semiconductor device 100 may include the first semiconductor chip 111, the second semiconductor chip 121, input/output terminals 115, the first molding member 119, wirings 117, etc. The input/output terminals 115 may be disposed adjacent to the second molding member 129 enclosing the second semiconductor chip 121.

In example embodiments, the second molding member 129 may include a material substantially the same as that of the first molding member 119. For example, each of the first and the second molding members 119 and 129 may include a polymer material such as epoxy compound. In this case, the second molding member 129 may be integrally formed with the first molding member 119. In FIG. 2, the second molding member 129 enclosing the second semiconductor chip 121 may have smaller dimensions than that of the first molding member 119 enclosing the first semiconductor chip 111, however, the second molding member 129 may have dimensions substantially the same as that of the first molding member 119.

As illustrated in FIG. 2, the second semiconductor chip 121 having a second connection pad 123 may be enclosed by the second molding member 129. Hence, the first semiconductor chip 111 having a first connection pad 113 may be protected by the first molding member 119, and also the second semiconductor chip 121 may be protected from an external environment such as a physical damage, a chemical reaction, an electrical shock, etc. Here, while the second molding member 129 may substantially enclose the second semiconductor chip 121, the second molding member 129 may be spaced apart from the input/output terminals 115 by a predetermined distance.

According to example embodiments, the package for the semiconductor device 100 may have a fan-out structure and also may have a configuration in which the second semiconductor chip 121 facing the first semiconductor chip 111 may be disposed at an inside of the fan-out structure where the input/output terminals 115 are not positioned. In addition, the package for the semiconductor device 100 may include the second molding member 129 to efficiently protect the second semiconductor chip 121 from the external environment. Since the package for the semiconductor device 100 may have a configuration which may include variations of arrangement of the components thereof, a space efficiency of the package for the semiconductor device 100 may sufficiently improved, and thus may have an improved degree of integration as compared to a conventional package for a semiconductor device having a fan-out structure.

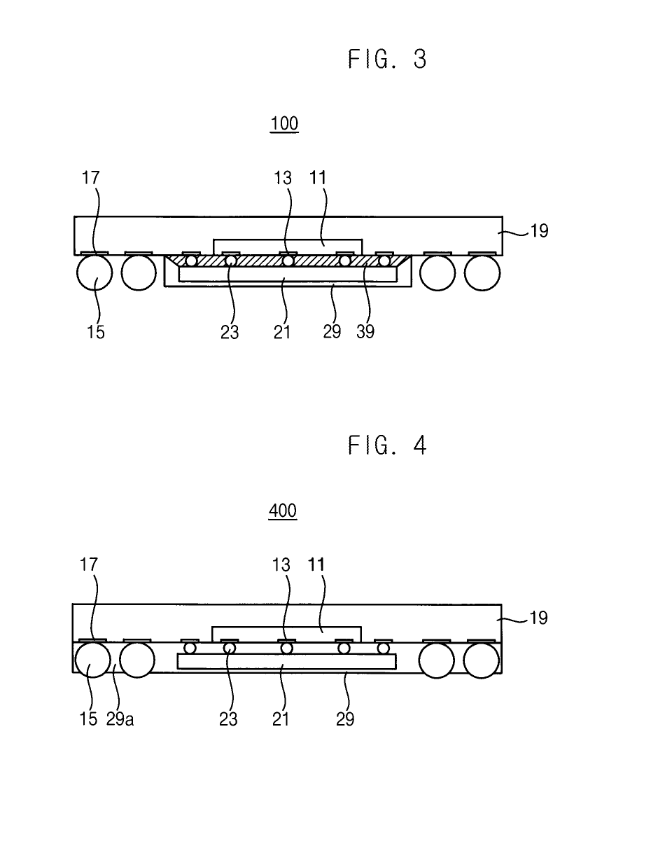

FIG. 3 is a cross-sectional view illustrating a package for a semiconductor device in accordance with some example embodiments of the invention. The package for the semiconductor device 200 illustrated in FIG. 3 may have a configuration substantially the same as or similar to that of the package for the semiconductor device 100 described with reference to FIG. 2 except a filling member 239 positioned between a first semiconductor chip 211 and a second semiconductor chip 221.

Referring to FIG. 3, the semiconductor device package 200 may include the filling member 239 disposed between the first semiconductor chip 211 and the second semiconductor chip 221. The filling member 239 may substantially bury a second connection pad 223 of the second semiconductor chip 221. The filling member 239 may be located between the first semiconductor chip 211 and the second semiconductor chip 221, and may contact a first molding member 219 and a second molding member 229. For example, the filling member 239 may under-fill between the first semiconductor chip 211 and the second semiconductor chip 221 which are substantially opposed to each other. The filling member 239 may include a filling resin. In example embodiments, the filling member 239 may substantially enclose some of wirings 219 which are disposed adjacent to the first semiconductor chip 211 and exposed through a bottom face of the first molding member 219. For example, the filling member 239 may substantially bury a first connection pad 213, the second connection pad 223 and some of the wirings 217.

In some example embodiments, the semiconductor device package 200 may have a configuration in which the filling member 239 is positioned between the first and the second semiconductor chips 211 and 221 without the second molding member 229 enclosing the second semiconductor chip 221.

According to example embodiments, the semiconductor device package 200 having a fan-out structure may include the second semiconductor chip 221 and the second molding member 220 which are disposed at an inside of the fan-out structure where the input/output terminals 215 are not located, so that the second semiconductor chip 221 may be protected from an external environment. Additionally, the semiconductor device package 200 may include a filling member 239 interposed between the first semiconductor chip 211 and the second semiconductor chip 221, such that a connection stability between the semiconductor chip 211 and the second semiconductor chip 221 may be improved. Accordingly, the semiconductor device package 200 may have an improved degree of integration and may provide an enhanced connection stability.

FIG. 4 is a cross-sectional view illustrating a semiconductor device package in accordance with some example embodiments of the invention. The semiconductor device package 300 illustrated in FIG. 4 may have a configuration substantially the same as or similar to that of the semiconductor device package 100 described with reference to FIG. 2 except a structure of a second molding member 329.

As illustrated in FIG. 4, the semiconductor device package 300 may include a first molding member 319 and the second molding member 329. The first molding member 319 may substantially enclose a first semiconductor chip 311 having a first connection pad 313 and the second molding member 329 may substantially enclose a second semiconductor chip 321 having a second connection pad 323.

In example embodiments, the second molding member 329 may have dimensions substantially the same as or similar to that of the first molding member 319. In this case, the second molding member 329 may be integrally formed with the first molding member 319. Therefore, input/output terminals 315 may be substantially covered with the second molding member 329. The second molding member 329 enclosing the second semiconductor chip 321 may have an extended portion 329a surrounding the input/output terminals 315. In this case, the input/output terminals 315 contacting wirings 317 may be partially exposed so as to be connected with an external device by the second molding member 329 having the extended portion 329a. For example, end portions of the input/output terminals 315 may protrude from the second molding member 329.

According to example embodiments, the semiconductor device package 300 may include the second molding member 329 having the extended portion 329a substantially enclosing the second semiconductor chip 321 and the input/output terminals 315. Thus, a connection stability between the input/output terminals 315 and the wirings 317 may be improved. Additionally, the first molding member 319 enclosing the first semiconductor chip 311 may have dimensions substantially the same as that of the second molding member 329 enclosing the second semiconductor chip 321, so that the semiconductor device package 300 may effectively protect the first and the second semiconductor chips 311 and 321 and also an overall structural stability of the semiconductor device package 300 may greatly increase while ensuring an improved degree of integration.

In some example embodiments, the semiconductor device package 300, similar to the filling member 239 of the semiconductor device package 200 described with reference to FIG. 3, may include a filling member (not illustrated) disposed between the first semiconductor chip 311 and the second semiconductor chip 321.

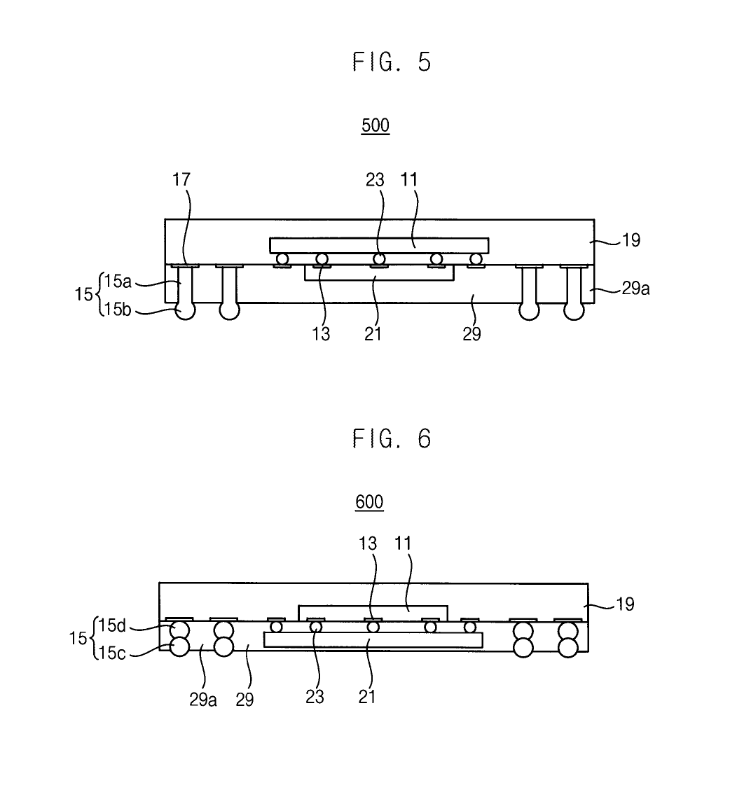

FIG. 5 is a cross-sectional view illustrating a semiconductor device package in accordance with some example embodiments of the invention. The semiconductor device package 400 illustrated in FIG. 5 may have a configuration substantially the same as or similar to that of the semiconductor device package 300 described with reference to FIG. 4 except input/output terminals 415 and a second semiconductor chip 421.

As illustrated in FIG. 5, the semiconductor device package 400 may include a first semiconductor chip 411 having at least one first connection pad 423, the second semiconductor chip 421 having at least one second connection pad 413, a first molding member enclosing the first semiconductor chip 411, the input/output terminals 415, a second molding member 429 enclosing the second semiconductor chip 421 and the input/output terminals 415, wirings 417 connected to the input/output terminals 415, etc. In this case, the first semiconductor chip 411 having the first connection pad 423 and the second semiconductor chip 321 having the second connection pad 413 may have structures substantially corresponding to those the first semiconductor chip 311 having the first connection pad 313 and the second semiconductor chip 321 having the second connection pad 323 described with reference to FIG. 4, respectively. That is, the semiconductor device package 400 illustrated in FIG. 5 may have a configuration in which arrangement of the first and the second semiconductor chips 411 and 421 is changed as compared with the semiconductor device packages 10, 100, 200 and 300 described with references to FIGS. 1 to 4. The second molding member 429 may have dimensions substantially the same as or similar to that of the first molding member 419, and also the first and the second molding members 419 and 429 may be substantially integrally formed.

In example embodiments, the second molding member 429 may include an extended portion 429a surrounding the input/output terminals 415 while partially exposing the input/output terminals 415. For example, end portions of the input/output terminals 415 may be protruded from the extended portion 429a of the second molding member 429. Each of the input/output terminals 415 may include a molding wiring 415a and a molding connection wiring 415b.

The molding wirings 415a may make contact with the wirings 417 through the extended portion 429a of the second molding member 420. According to example embodiments, a via hole, which passes through the extended portion 429a of the second molding member 429 and exposes the wirings 17, may be formed, and then the via hole may be filled with a conductive material to thereby form the molding wiring 415a. For example, the molding wiring 415a may be extended onto a surface of the extended portion 429a of the second molding member 429 from the wiring 417.

The molding connection wiring 415b may be substantially integrally formed with the molding wiring 415a and may be protruded from the extended portion 429a of the second molding member 429. An external device may be electrically connected to the molding connection wiring 415b. For example, the molding connection wiring 415b may have a shape of a solder ball.

When the semiconductor device package has a configuration in which a plurality of first semiconductor chips are stacked as described below, a thickness of the first molding member substantially enclosing the first semiconductor chips may become thicker continuously. Accordingly, when the input/output terminals are formed through the first molding member, a process forming via holes for the input/output terminals and a process filling conductive materials in the via holes may not be precisely performed. In example embodiments, the input/output terminals passing through the first molding member enclosing stacked first semiconductor chips may be easily formed using the input/output terminals 415 passing through the second molding member 429. In this case, after forming the via holes in the first molding member, conductive materials may be filled in the via holes to form the input/output terminals passing through the first molding member.

In example embodiments, the input/output terminals 415 may have the molding wirings 415a connected to the wirings 417 through the extended portion 429a of the second molding member 429, such that connection stabilities between the wirings 417 and the input/output terminals 415 may be improved even though a thickness of the second molding member 429 is relatively large. Accordingly, the second semiconductor chip 421 may be effectively protected and the input/output terminals 415 may be stably connected to the wirings 417.

FIG. 6 is a cross-sectional view illustrating a semiconductor device package in accordance with some example embodiments of the invention. The semiconductor device package 500 illustrated in FIG. 6 may have a configuration substantially the same as or similar to that of the semiconductor device package 400 described with reference to FIG. 5 except input/output terminals 515.

Referring to FIG. 6, the semiconductor device package 500 may include the input/output terminals 515 having a substantially stacked structure. A first molding member 519 enclosing a first semiconductor chip 511 having a first connection pad 513 may have dimensions substantially the same as or similar to that of a second molding member 529 enclosing a second semiconductor chip 521 having a second connection pad 523.

In example embodiments, input/output terminals 515 may pass through an extended portion 529a of the second molding member 529, and then may make contact with wirings 517. For example, each of the input/output terminals 515 may include two stacked solder balls 515c and 515d. Here, one solder ball 515c may be contacted with the wirings 517 and the other solder ball 515d may be exposed from the extended portion 529a of the second molding member 529. Although each of the input/output terminals 515 includes two solder balls 515c and 515d in FIG. 6, the number of solder balls may vary according to dimensions and/or a shape of the semiconductor device package 500.

According to example embodiments, the semiconductor device package 500 of a fan-out structure may include the input/output terminals 515 having a structure in which solder balls are stacked, so that connection stabilities between the input/output terminals 515 and the wirings 517 may be ensured and also the first and the second semiconductor chips 511 and 521 may be protected effectively by the first and the second molding members 519 and 529.

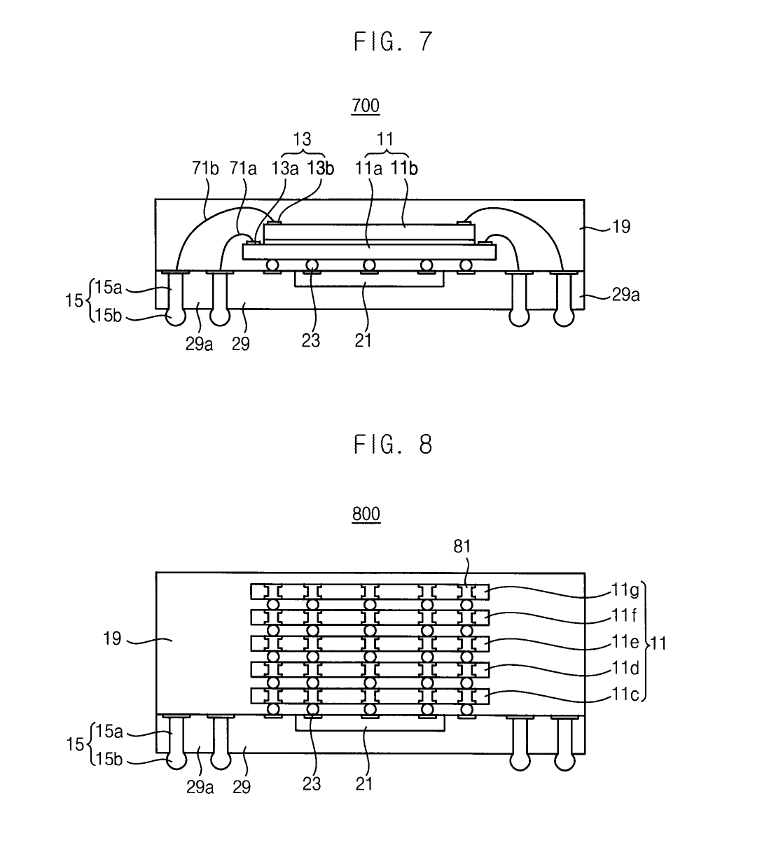

FIG. 7 is a cross-sectional view illustrating a semiconductor device package in accordance with some example embodiments of the invention. The semiconductor device package 600 illustrated in FIG. 7 may have a configuration substantially the same as or similar to that of the semiconductor device package 400 described with reference to FIG. 5 except a first semiconductor chip unit 611.

As illustrated in FIG. 7, the semiconductor device package 600 may include the first semiconductor chip unit 611 having a structure in which at least two first semiconductor chips 611a and 611b are stacked. In this case, the second semiconductor chip 621 may be opposed to the first semiconductor chip 611 at an inside of the fan-out structure where input/output terminals 615 are not positioned. In the semiconductor device package 600 illustrated in FIG. 7, the first semiconductor chip unit 611 having connection pads 613 may include two first semiconductor chips 611a and 611b, however, the number of the first semiconductor chips may vary as occasion demands.

A first molding member 619 may entirely enclose the first semiconductor chip unit 611 including stacked semiconductor chips 611a and 611b. A second molding member 629 may enclose the second semiconductor chip 621 and may include an extended portion 629a partially exposing the input/output terminals 615. Each of the input/output terminals 615 may include a molding wiring 615a connected to the wirings and a connection wiring 615b connected to the molding wiring 615a. For example, the connection wiring 615b may be substantially integrally formed with the molding wiring 615a.

In example embodiments, each of first connection pads 613a and 613b of the semiconductor chips 611a and 611b may be connected to the wirings to which the input/output terminals 615 are connected by connection members 671a and 671b. That is, the input/output terminals 615 may be electrically connected to the first semiconductor chips 611a and 611b by the connection members 671a and 671b and the wirings. For example, each of the connection members 671a and 671b may have a shape of a wire. The lowermost first semiconductor chip 611a of the first semiconductor chip unit 611 may be connected to the second semiconductor chip 621 by additional connection pad 623. For example, the additional connection pad 623 of the first semiconductor chip 611a may make contact with a connection pad of the second semiconductor chip 621.

In the first semiconductor chip unit 611 illustrated in FIG. 7, the first semiconductor chips 611a and 611b may have dimensions substantially the same as or similar to each other although the first semiconductor chips 611a and 611b have different dimensions in FIG. 7. Further, the connection members 671a and 671b may electrically connect the first connection pads 613a and 613b with the input/output terminals 615 in accordance with a circuit configuration. Alternatively, the connection member 671a and 671b may connect the first semiconductor chips 611a and 611b to other components, or may connect the input/output terminals 615 to other components.

FIG. 8 is a cross-sectional view illustrating a semiconductor device package in accordance with some example embodiments of the invention. The semiconductor device package 700 illustrated in FIG. 8 may have a configuration substantially the same as or similar to that of the semiconductor device package 400 described with reference to FIG. 5 except a first semiconductor chip unit 711.

Referring to FIG. 8, the semiconductor device package 700 may include the first semiconductor chip unit 711 having five stacked first semiconductor chips 711c, 711d, 711e, 711f and 711g. A second semiconductor chip 721 may be opposed to the lowermost first semiconductor chip 711c of the first semiconductor chip unit 711 at an inside of the semiconductor device package 700 having a fan-out structure. In some embodiments, the first semiconductor chip unit 711 may have more or less than five stacked first semiconductor chips.

A first molding member 719 may entirely enclose the first semiconductor chip unit 711 including the first semiconductor chips 711c, 711d, 711e, 711f and 711g. A second molding member 729 may substantially surround the second semiconductor chip 721. Each of input/output terminals 715 may include a molding wiring 715a and a connection wiring 715b. The connection wirings 715b of the input/output terminals 715 may be exposed from an extended portion 729a of the second molding member 729.

In example embodiments, the first semiconductor chips 711c, 711d, 711e, 711f and 711g are electrically connected to one another using a through-silicon via (TSV) wiring 781. For example, the first semiconductor chips 711c, 711d, 711e, 711f and 711g may have the TSV wirings 781, respectively. First connection pads of the first semiconductor chips 711c, 711d, 711e, 711f and 711g may be electrically connected to one another by the TSV wirings 781. Here, the lowermost first semiconductor chip 711c of the first semiconductor chip unit 711 may be electrically connected to the second semiconductor chip 721. That is, a first connection pad of the lowermost first semiconductor chip 711c of the first semiconductor chip unit 711 may make contact with a second connection pad 723 of the second semiconductor chip 721.

The semiconductor device packages 600 and 700 described with reference to FIGS. 7 and 8 may respectively include the first semiconductor chip units 611 and 711 in which a plurality of the first semiconductor chips 611a, 611b, 711 c, 711d, 711e, 711f and 711g are stacked. Accordingly, each of the semiconductor device package 600 and 700 may accomplish an improved degree of integration and may improve electrical connection stabilities among the input/output terminals 615 and 715 and the first semiconductor chip units 611 and 711 by the connection members 671a and 671b or the TSV wirings 781. Further, the input/output terminals 615 and 715 may be formed in the second molding members 629 and 729, respectively, so that manufacturing processes for the input/output terminals 615 and 715 may be simplified.

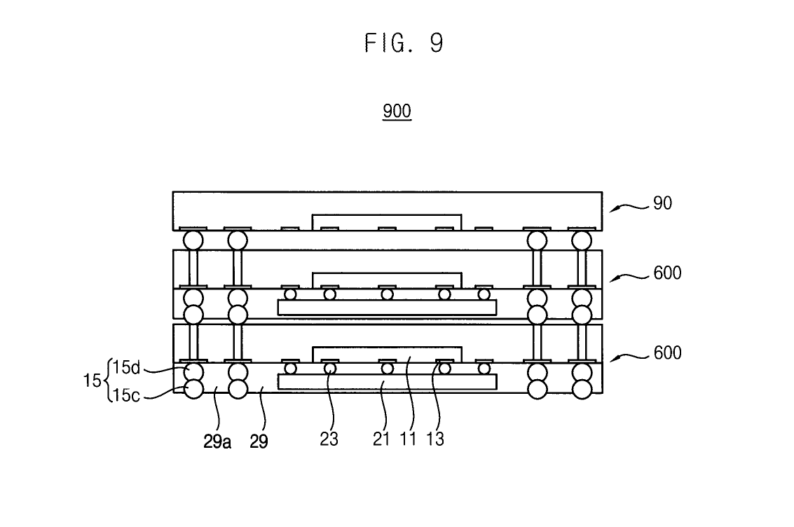

FIG. 9 is a cross-sectional view illustrating a semiconductor device package in accordance with some example embodiments of the invention.

The semiconductor device package 800 illustrated in FIG. 9 may have a structure in which the semiconductor device packages 500 described with reference to FIG. 6 are stacked. Further, the semiconductor device package 800 may include an additional semiconductor device package 890 substantially the same as or similar to a conventional semiconductor device package having a fan-out structure. In this case, the additional semiconductor device package 890 may be disposed on the semiconductor device packages 500.

In example embodiments, input/output terminals 515 and wirings may be connected to one another by through wirings, so that the semiconductor device packages 500 may be electrically connected to each other. For example, each of the through wirings may electrically connect the input/output terminals 515 of one semiconductor device package 500 with wirings of another semiconductor device package 500.

In some example embodiments, the semiconductor device package 800 may have a configuration in which the semiconductor device packages described with references to FIGS. 1 to 5 and the additional semiconductor device package 890 are stacked.

According to example embodiments, the semiconductor device package 800 may include semiconductor chips disposed at the inner side of the fan-out structure where the input/output terminals are not located. Therefore, a space efficiency of the semiconductor device package 800 may be sufficiently improved so that an improved degree of integration thereof may be ensured. Further, the semiconductor device package 800 may include the input/output terminals passing through the second molding member, such that connection stabilities among the input/output terminals and the wirings may be sufficiently improved to thereby enhance a reliability of the semiconductor device package 800.

The foregoing is illustrative of embodiments and is not to be construed as limiting thereof. Although a few embodiments have been described, those skilled in the art will readily appreciate that many modifications are possible in the embodiments without materially departing from the novel teachings and advantages of the invention. Accordingly, all such modifications are intended to be included within the scope of the invention as defined in the claims. In the claims, means-plus-function clauses are intended to cover the structures described herein as performing the recited function and not only structural equivalents but also equivalent structures. Therefore, it is to be understood that the foregoing is illustrative of various embodiments and is not to be construed as limited to the specific embodiments disclosed and that modifications to the disclosed embodiments, as well as other embodiments, are intended to be included within the scope of the appended claims.

What is claimed is:

1. A package for a semiconductor device having a fan-out structure in which input/output terminals are disposed adjacent to at least one first semiconductor chip and electrically connected to the at least one first semiconductor chip, the package for the semiconductor comprising:
a second semiconductor chip spaced apart from the input/output terminals, the second semiconductor chip being opposed to the at least one first semiconductor chip.

2. The semiconductor device package of claim 1, further comprising:
a first molding member enclosing the first semiconductor chip; and
a second molding member enclosing the second semiconductor chip.

3. The semiconductor device package of claim 2, further comprising a filling member disposed between the first semiconductor chip and the second semiconductor chip.

4. The semiconductor device package of claim 2, wherein the second molding member includes an extended portion surrounding the input/output terminals and the input/output terminals are partially exposed form the extended portion.

5. The semiconductor device package of claim 4, wherein each of the input/output terminals includes a molding wiring passing through the extended portion of the second molding member and a connection wiring protruding from the extended portion.

6. The semiconductor device package of claim 4, wherein each of the input/output terminals includes a stacked solder ball buried in the extended portion of the second molding member and exposed from the extended portion.

7. The semiconductor device package of claim 4, further comprising wirings buried in the first molding member and connected to the input/output terminals.

8. The semiconductor device package of claim 1, wherein the first semiconductor chip includes a first connection pad and the second semiconductor chip includes a second connection pad contacting the first connection pad.

9. The semiconductor device package of claim 1, further comprising:
a plurality of first semiconductor chips stacked on the second semiconductor chip;
a first molding member enclosing the plurality of first semiconductor chips; and
a second molding member enclosing the second semiconductor chip.

10. The semiconductor device package of claim 9, wherein the input/output terminals pass through the second molding member, each of the first semiconductor chips includes a connection pad, and further comprising a connection member electrically connecting the connection pad with the input/output terminals.

11. The semiconductor device package of claim 9, further comprising through-silicon via (TSV) wirings electrically connecting the first semiconductor chips to each other.
